(19) United States
(12) Patent Application Publication
(10) Pub. No.: US 2006/0151841 A1
(43) Pub. Date: Jul. 13, 2006

(54) Pillar nonvolatile memory layout methodology

(76) Inventor: Fuh-cheng Jong, Tainan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/033,149

(22) Filed: Jan. 12, 2005

(51) Int. Cl. H01L 29/76; H01L 29/94; H01L 31/062; H01L 31/113; H01L 31/119

(52) U.S. Cl. 257/390

(57) ABSTRACT

A pillar nonvolatile memory layout methodology includes an arrangement of multiple pillar transistors spaced at intervals on a chip; surrounded in sequence by a SiO2 layer, a floating gate, a dielectric, and a control gate; a separation layer being formed between any two abutted pillar transistors; one up two surfaces of each pillar transistor being connected with a word line and a bit line at right angle to each other; and the word line and the control gate of the pillar transistor being connected to each other while the bit line and the drain being connected to each other respectively and independently as the bit line and the word line being vertical to each other to separate and insulate each pillar transistor for providing one up to four-bit data storage capacity.

### BACKGROUND OF THE INVENTION

(a) Field of the Invention

The present invention relates to a layout methodology for a pillar nonvolatile memory, and more particularly, to one that a bit line and a word line are vertical to each other and connected respectively and individually to separate and insulate each pillar transistor for providing one up to four-bit data storage capacity.

(b) Description of the Prior Art

Though comparatively available in the market today, a pillar nonvolatile memory can be given larger memory capacity through the manufacturing process and cell configuration. In theory, the pillar nonvolatile memory can be made having up to four bits; that is, one bit for each pillar surface (the number of the bit may vary depending on the consideration of certain factors). Therefore, there is the great potential in the development of the pillar nonvolatile memory.

However, so far there is the absence of a complete and matured technology involving the layout of multi-bit nonvolatile memory in pillar configuration. Furthermore the problem of reducing body effect by causing the voltage difference between the source and the base to approach zero is pending solutions.

### SUMMARY OF THE INVENTION

The primary purpose of the present invention is to provide a methodology allowing different layout planning for a pillar nonvolatile memory with different bit number of storage so to achieve the optimal option of layout methodology for the pillar nonvolatile memory taking the manufacturing process, design and cost factors into consideration.

To achieve the purpose, multiple pillar transistors are arranged at intervals on a chip with a drain above the transistor; and a source, below. The pillar surfaces of the pillar transistor serve as channels to connect both of the source and the drain and the channel is surrounding by a SiO2 layer, a floating gate, a dielectric and a control gate in sequence. A separation layer is formed between any two abutted pillar transistors. One up to four surfaces of each pillar transistor is connected to a word line, and to a bit line in the direction at right angle to the word line. The word line extends to connect to the control gate of each pillar transistor on the same surface while the bit line extends to connect to the drain of each pillar transistor on the same surface. Accordingly, by having both of the word line and the bit line respectively and independently connected vertical to each other, each pillar transistor is separated and insulated to provide storage capacity of one up to four bits.

### BRIEF DESCRIPTION OF THE DRAWINGS

FIG. 1 is a perspective view showing a pillar transistor of the present invention.

FIG. 2 is a schematic view showing one-bit connection layout of the present invention.

FIG. 3 is a schematic view showing one-bit jump layout of the present invention.

FIG. 4 is a schematic view showing two-bit connection layout of the present invention.

FIG. 5 is a schematic view showing two-bit jump layout of the present invention.

FIG. 6 is a schematic view showing three-bit connection layout of the present invention.

FIG. 7 is a schematic view showing three-bit jump layout of the present invention.

FIG. 8 is a schematic view showing four-bit connection layout of the present invention.

FIG. 9 is a schematic view showing four-bit jump layout of the present invention.

FIG. 10 is a schematic view showing a shared word line of another preferred embodiment of the present invention.

### DETAILED DESCRIPTION OF THE PREFERRED EMBODIMENTS

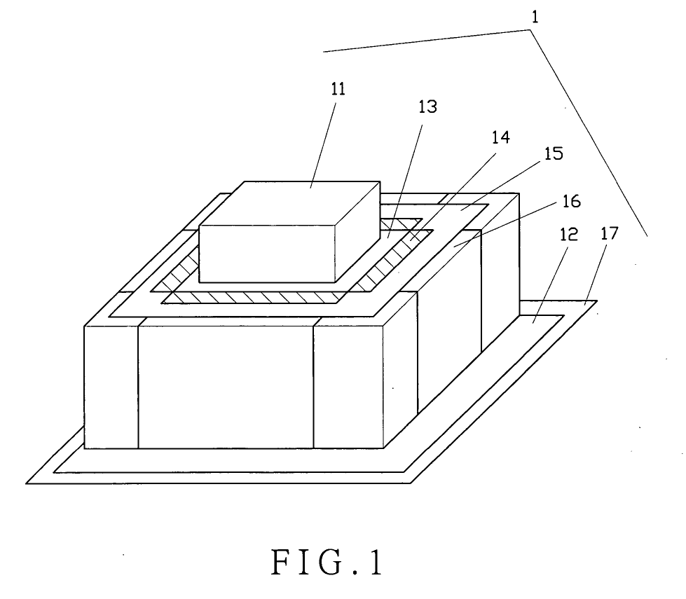

Referring to FIG. 1, the present invention is essentially having multiple square, pillar transistors (1) arranged in rows and spaced at intervals on a silicon chip (17). A drain (11) of the transistor (1) is located at the top of the transistor (1) while a source (12) is located below the transistor (1). Each surface of the transistor (1) is a channel (not illustrated/covered by a SiO₂ layer (13)) used to connect the drain (11) and the source (12). The SiO₂ layer (13) surrounds the channels; and the SiO2 layer (13) is further surrounded by a floating gate (14) comprised of silicone nitride or silicon to store charges coming from the channels for reference by storage logic level. A dielectric (15) made of SiO2 or SiO2-silicone nitride-SiO2 (ONO) surrounds the floating gate (14) and a control gate (16) to control the amperage of the channels further surrounds the dielectric (15).

There are four vertical surfaces to each transistor (1) with each cell of the transistor (1) capable of respectively storing one bit, two bits, three bits or four bits to increase its memory capacity up to four times. Whereas the pillar nonvolatile memory is a multi-bit cell instead of a multi-level cell and provided with the restriction of a word line and a bit line being vertical to each other, it is prevented from having the word line and the bit line to be vertical to each other on a physical no matter how each pillar transistor (1) may be applied for how many bits even in the stage of arrangement due to factors of cost, circuit design or the manufacturing process. Nonetheless, both of the word line and the bit line should be made vertical to each other in terms of the planning of circuit functions to avoid error in the coordination between the word line and the bit line. The layout of the word line and the bit line of the present invention is respectively described below in terms of one up to four bits.

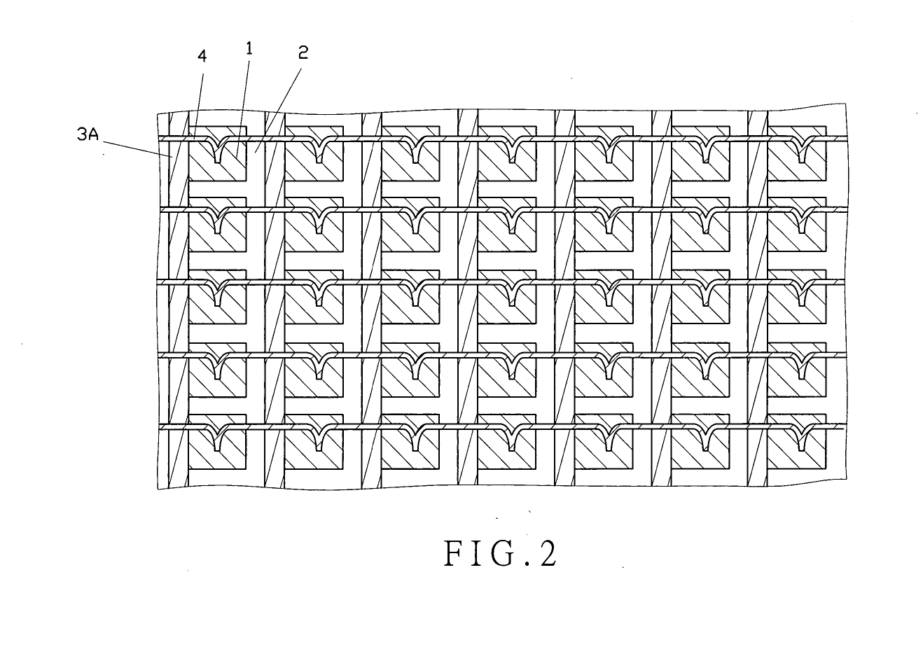

In the layout for one-bit connection as illustrated in FIG. 2 is applicable to that there is only one surface bit for each square, pillar transistor (1). A separation layer (2) made of insulating material is formed between any two abutted pillar transistors (1). One surface of each pillar transistor (1) is connected to a word line (3A) and connected to a bit line (4) in the direction vertical to the word line (3A). Since the memory capacity for each surface of the pillar transistor (1) is only one bit, the layout between the word line (3A) and the bit line (4) is the one-on-one relation as seen in the Cartesian coordinates in mathematics. Wherein as also illustrated in FIG. 1, the word line (3A) extends to connect to the control gate (16) of each pillar transistor (1) on the same surface while the bit line (4) is connected to drain (11) of each pillar transistor (1) extending in the same direction so that both of the bit line (4) and the word line (3A) are respectively and independently connected while being vertical to each other. Accordingly, each pillar transistor (1) is separated and insulated to provide one-bit data storage capacity.

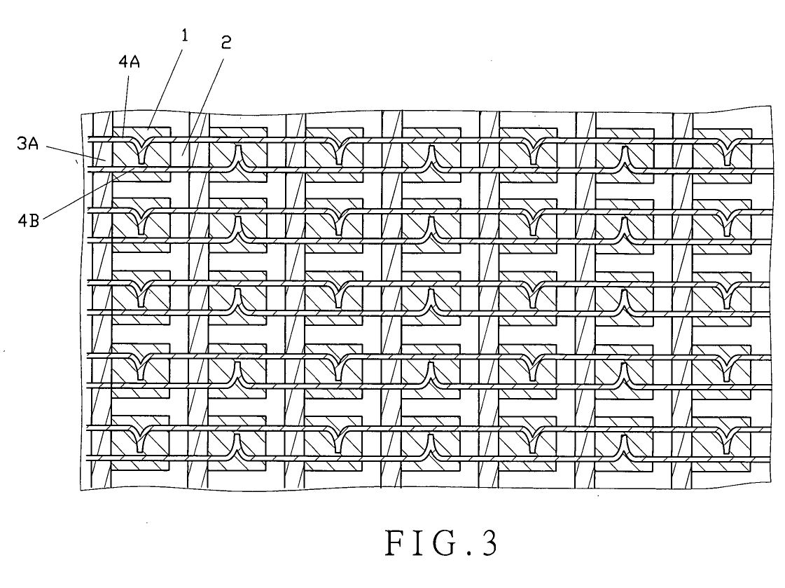

As illustrated in FIG. 3, a jump arrangement for one bit is applicable to that only a single surface bit is available to each square, pillar transistor (1). The separation layer (2) made of insulating material is formed between any two abutted pillar transistors (1). On one surface of each pillar transistor (1) is connected to the word line (3A) extending to further connect to the control gate (16) of each pillar transistor (1) as also illustrated in FIG. 1 and to upwardly connect to two bit lines (4A, 4B) in the direction vertical to the word line (3A). Meanwhile both bit lines (4A, 4B) are connected to the drain (11) of each pillar transistor (1) extending in the same direction. One bit line (4A) is connected to those pillar transistors (1) arranged in odd sequence; and the other bit line (4B), even sequence for each of pillar transistor (1) to indicate jump status. Accordingly, each pillar transistor (1) is separated and insulated by having each of both bit lines (4A, 4B) and the word line (3A) are vertical to each other and respectively and independently connected to provide one-bit data storage capacity.

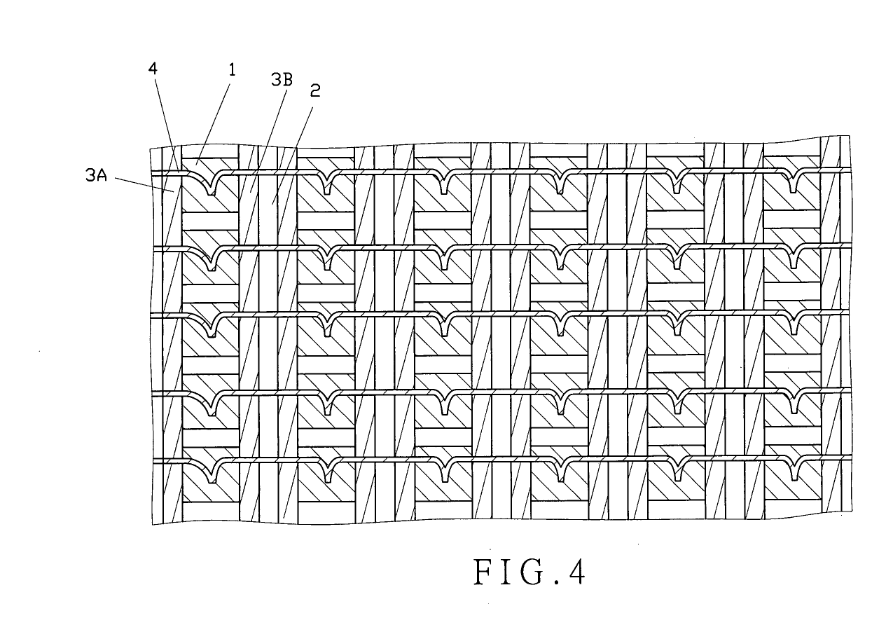

Now referring to FIG. 4, a 2-bit connection layout is applicable to each square, pillar transistor (1) that is provided with two surfaces bits. The separation layer (2) made of insulating material is formed between any two abutted pillar transistors (1). Two surfaces of each pillar transistor (1) are connected with two word lines (3A, 3B) respectively extending to connect the control gate (16) of each pillar transistor (1) on the same surface also as illustrated in FIG. 1. One word line (3A) controls the bit on one surface of each of all pillar transistors (1) while the other word line (3B) controls the bit on another surface of each of all pillar transistors (1). The bit line (4) is connected to the pillar transistor (1) in a direction the pillar transistor (1) is vertical to either of the word line (3A, or 3B), and also connected to the drain (11) of each pillar transistor (1) extending in the same direction also as illustrated in FIG. 1. Accordingly, with each of both word lines (3A, 3B) and the bit line (4) being vertical to each other and respectively and independently connected, the pillar transistor (1) is separated and insulated to provide two-bit data storage capacity.

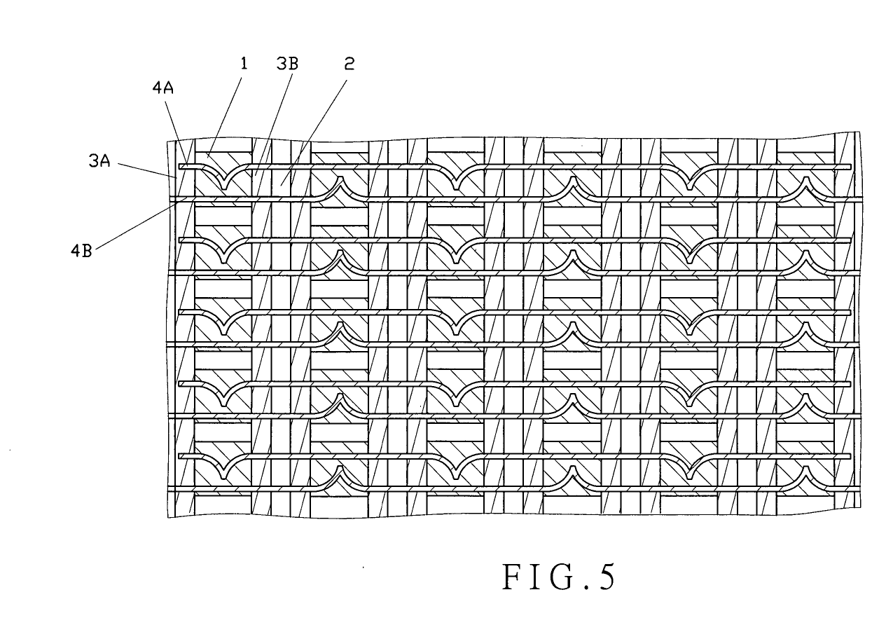

As illustrated in FIG. 5 for a 2-bit jump layout, the layout is applicable to each square, pillar transistor (1) that is provided with two surfaces bits. The separation layer (2) made of insulating material is formed between any two abutted pillar transistors (1). Two surfaces of each pillar transistor (1) are connected with two word lines (3A, 3B) respectively extending to connect the control gate (16) of each pillar transistor (1) on the same surface also as illustrated in FIG. 1 and further connected to two bits lines (4A, 4B) in the direction vertical to both of the word lines (3A, 3B). Meanwhile, both bit lines (4A, 4B) are connected to the drain (11) of each pillar transistor (1) extending in the same direction. The bit line (4A) is connected to the row of the pillar transistors (1) in odd sequence; and another bit line (4B), even sequence so as that all pillar transistors (1) indicate jump status among one another to separate and insulate each pillar transistor (1) to provide two-bit data storage capacity.

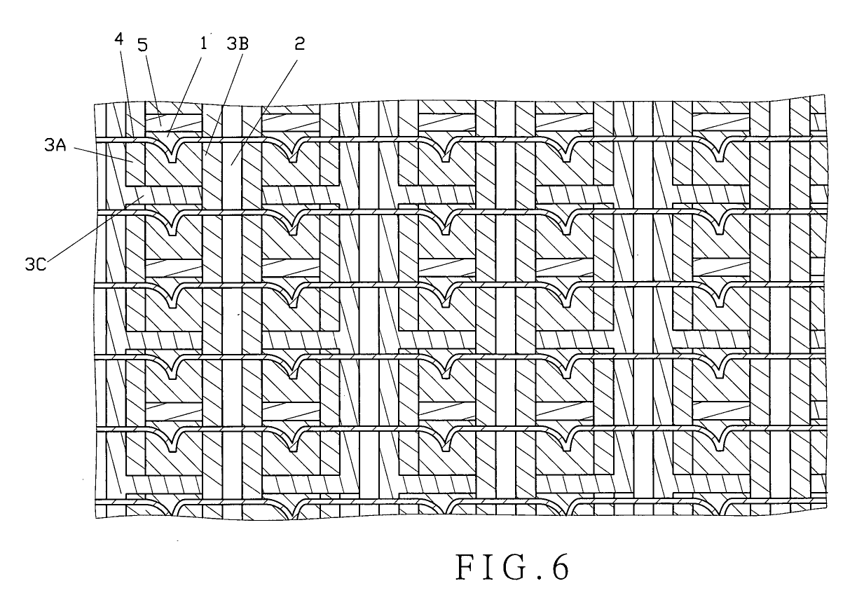

FIG. 6 shows a 3-bit connection layout applicable to each square, pillar transistor (1) that is provided with three surfaces bits. The separation layer (2) made of insulating material is formed between any two abutted pillar transistors (1). Three surfaces of each pillar transistor (1) are connected with three word lines (3A, 3B, 3C) with the remaining surfaces of the pillar transistor (1) left for the user by a source shortage (5) to reduce body effect. All those three word lines (3A, 3B, 3C) respectively extend to connect the control gate (16) of each pillar transistor (1) on the same surface. Wherein, the word line (3C) is first connected to the control gate (16) in a direction vertical to those two word lines (3A, 3B) also as illustrated in FIG. 1 before shifting to the same direction as that of those two word lines (3A, 3B). The word line (3A) controls the bits on one surface of each of all the pillar transistors (1); and the other word line (3B), those from another surface. A bit line (4) is connected in the direction where the pillar transistor (1) in vertical respectively to those word lines (3A, 3B, 3C) and further connected to the drain (11) of each pillar transistor (1) extending in the same direction also as illustrated in FIG. 1. Accordingly, with each of those three word lines (3A, 3B, 3C) and the bit line (4) being vertical to each other and respectively and independently connected, the pillar transistor (1) is separated and insulated to provide three-bit data storage capacity. In this preferred embodiment, a separation layer made of insulation material is formed between any abutted rows of the transistor (1) to separate the word line (3B) between any abutted rows of the transistor (1), thus to ensure the accuracy of data transmission by each word line (3B).

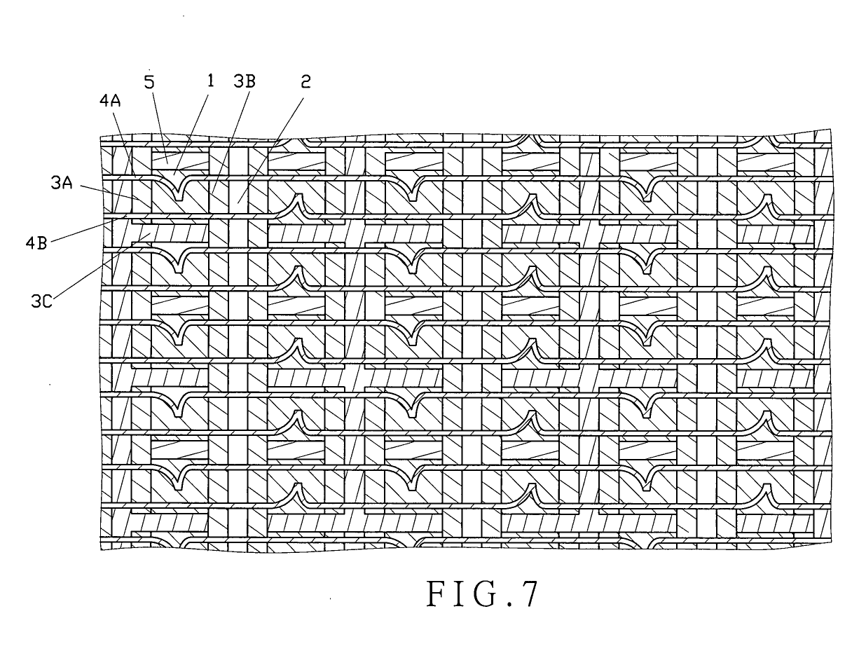

As illustrated in FIG. 7, a 3-bit jump layout is applicable to each square, pillar transistor (1) provided with three-surface bit. The separation layer (2) made of insulating material is formed between any two abutted pillar transistors (1). Three surfaces of each pillar transistor (1) are connected with three word lines (3A, 3B, 3C) with the remaining surfaces of the pillar transistor (1) left for the user by the source shortage (5) to reduce body effect. All those three word lines (3A, 3B, 3C) respectively extend to connect the control gate (16) of each pillar transistor (1) on the same surface. The word line (3C) is first connected to the control gate (16) also as illustrated in FIG. 1 in a direction vertical to the other two word lines (3A, 3B) before shifting to the same direction as that of the other two word lines (3A, 3B). The word line (3A) controls the bits on one surface of each of all the pillar transistors (1); and the other word line (3B), those on another surface. Two bit lines (4A, 4B) are connected in the direction vertical to each of those word lines (3A, 3B, 3C) and further connected to the drain (11) of each pillar transistor (1) extending in the same direction also as illustrated in FIG. 1. The bit line (4A) is connected to those pillar transistors (1) in the row of odd connection sequence; and the other bit line (4B), even connection sequence. Accordingly, each pillar transistor (1) indicates jump status with another. With both of the bit lines (4A, 4B) are respectively and independently connected in vertical to those word lines (3A, 3B, 3C), each pillar transistor (1) is separated and insulated for providing 3-bit data storage capacity.

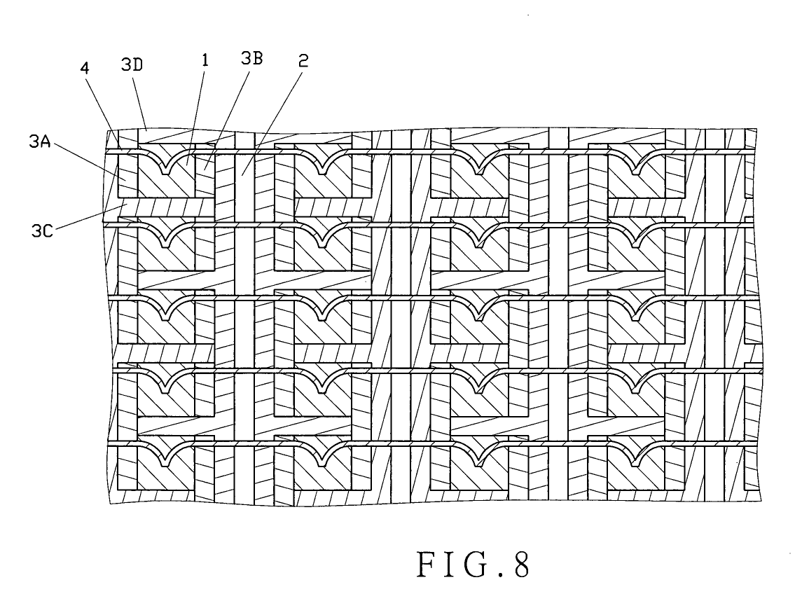

As illustrated in FIG. 8, a 4-bit connection layout is applicable to each square, pillar transistor (1) provided with four-surface bit. The separation layer (2) comprised of insulating material is formed between any two abutted pillar transistors (1). Four surfaces are respectively connected with a word line (3A 3B, 3C, 3D). The word lines (3A, 3B, 3C, 3D) respectively extend to connect the control gate (16) of each pillar transistor (1) on the same surface. Both word lines (3C, 3D) are connected to the control gate (16) also as illustrated in FIG. 1 in a direction vertical to another two word lines (3A, 3B) before shifting to the same direction as that of those two word lines (3A, 3B). The word line (3A) controls the bits on one surface of each of all the pillar transistors (1); and another word line (3B), those on the other surface. The bit line (4) is connected to the pillar transistor (1) in a direction respectively vertical to those word lines (3A, 3B, 3C, 3D) and is further connected to the drain (11) of each pillar transistor (1) extending in the same direction as also illustrated in FIG. 1. Accordingly, with the bit line (4) respectively and independently connected in vertical to the word lines (3A, 3B, 3C, 3D), each pillar transistor (1) is separated and insulated to provide four-bit data storage capacity.

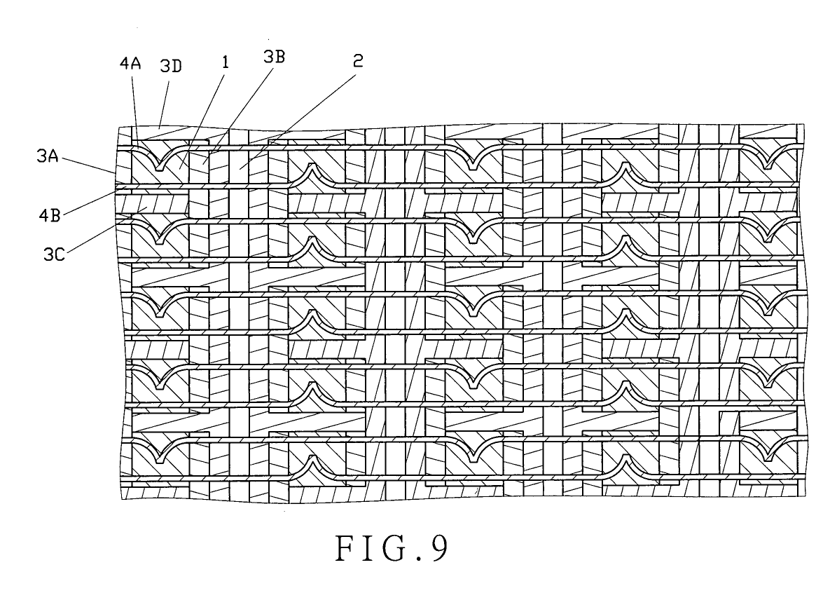

In a 4-bit jump layout applicable to that each square, pillar transistor (1) is provided with four-surface bit as illustrated in FIG. 9, the separation layer (2) is formed between any two abutted pillar transistors (1) and four word lines (3A, 3B, 3C, 3D) are respectively connected on four surfaces of each pillar transistor (1). The four word lines (3A, 3B, 3C, 3D) extend to connect to the control gate (16) of each pillar transistor (1) on the same surface as also illustrated in FIG. 1. Wherein, two word lines (3C, 3D) are first connected to the control gate (16) as also illustrated in FIG. 1 in a direction vertical to another two word lines (3A, 3B) before shifting to the same direction as that of the two lines (3A, 3B). The word line (3A) controls the bits on one surface of each of all the transistors (1); and another word line (3B), those on the other surface. Two bit lines (4A, 4B) are connected in the direction vertical to the four word lines (3A, 3B, 3C, 3D) and further connected to the drain (11) of each pillar transistor (1) extending in the same direction as also illustrated in FIG. 1. The bit line (4A) is connected to those pillar transistors (1) arranged in the rows of odd sequence; and the other bit line (4B), those in even sequence for each pillar transistor (1) to indicate jump status with any other pillar transistor (1). With those bit lines (4A, 4B) and those word lines (3A, 3B, 3C, 3D) in vertical to one another and respectively and independently connected to separate and insulate each pillar transistor for providing four-bit data storage capacity.

Therefore, depending on the storage bit, the layout for the pillar nonvolatile memory is planned to achieve the optimal option of the layout by taking factors of manufacturing process, design, and cost into consideration.

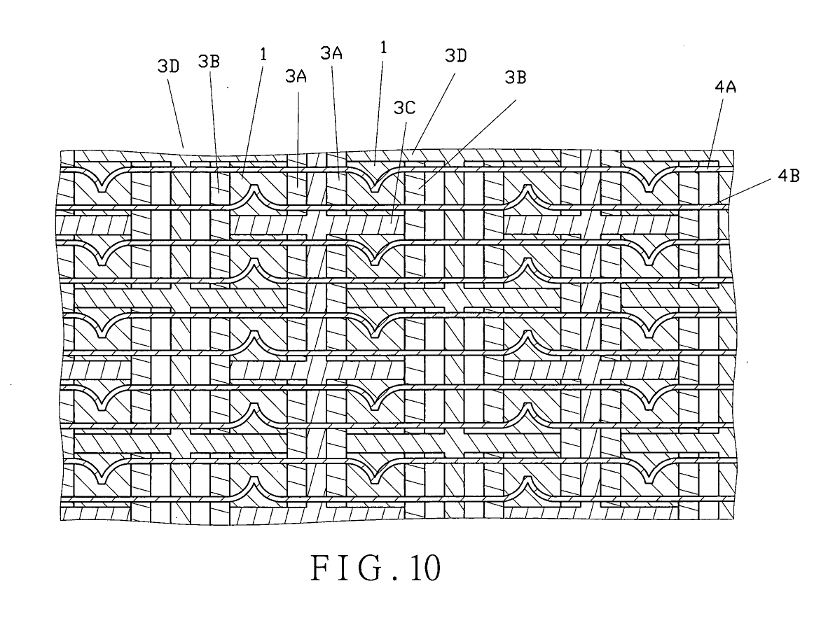

In another preferred embodiment of the present invention as illustrated in FIG. 10, the word line (3A or 3B) in vertical to the bit lines (4A, 4B) is available for shared connection for its abutted pillar transistor (1) thus to reduce the consumption of material, the area, and the production cost.

I claim:

1. A pillar nonvolatile memory layout methodology comprising an arrangement of multiple square, pillar transistors spaced at intervals on a chip; a drain of the transistor being provided above the transistor, and a source, below; pillar surfaces of the transistor serving as channels to connect the source and the drain; the channels being surrounded by a SiO2 layer, a floating gate, a dielectric, and a control gate in sequence; a separation layer being formed between any two abutted transistors; one or multiple pillar surface of the transistor being connected to a word line, and connected to a bit line in the direction at right angle to the word line; the word line being extended and connected to the control gate of each transistor on the same surface, and the bit line, to the drain; both the bit line and the word line being vertical to each other and connected respectively and independently to separate and insulate each transistor; and the pillar surface provided with the word line of each transistor to provide one-bit data storage capacity.

2. The pillar nonvolatile memory layout methodology of claim 1, wherein two word lines are provided with one being connected to the pillar transistors arranged in odd sequence and the other being connected to the pillar transistors arranged in even sequence; and the connection between any two abutted pillar transistors is made in the fashion of jump to each other.

3. The pillar nonvolatile memory layout methodology of claim 1, wherein the floating gate is comprised of silicon.

4. The pillar nonvolatile memory layout methodology of claim 1, wherein the floating gate is comprised of silicon nitride.

5. The pillar nonvolatile memory layout methodology of claim 1, wherein the dielectric is comprised of silicon dioxide.

6. The pillar nonvolatile memory layout methodology of claim 1, wherein the dielectric is comprised of silicon dioxide-silicone nitride-silicon dioxide.

7. The pillar nonvolatile memory layout methodology of claim 1, wherein the word line vertical to the bit line is available for shared connection with its abutted pillar transistor.

8. The pillar nonvolatile memory layout of claim 1, wherein three surfaces of each pillar transistor are connected with word lines;
the separation layer is formed between two rows of the pillar transistors to separate the word lines between any two abutted pillar transistors of each row.

9. The pillar nonvolatile memory layout methodology of claim 1, wherein the separation layer is made of insulating material.
